(19) United States
(12) Patent Application Publication
(10) Pub. No.: US 2025/0262981 A1
(43) Pub. Date: Aug. 21, 2025

(54) METHOD FOR DIAGNOSING AGING OF MAIN HIGH VOLTAGE BATTERY IN DUAL BATTERY SYSTEM AND SYSTEM FOR THE SAME

(71) Applicants: HYUNDAI MOTOR COMPANY, Seoul (KR); Kia Corporation, Seoul (KR)

(72) Inventor: Dae Won Yang, Hwaseong-si (KR)

(73) Assignees: HYUNDAI MOTOR COMPANY, Seoul (KR); Kia Corporation, Seoul (KR)

(21) Appl. No.: 18/937,970

(22) Filed: Nov. 5, 2024

(30) Foreign Application Priority Data
Feb. 20, 2024 (KR) 10-2024-0024307

(51) Int. Cl. B60L 58/16

(52) U.S. Cl. CPC B60L 58/16; B60L 2240/545; B60L 2240/547; B60L 2240/549

(57) ABSTRACT

A vehicle may include a motor system configured to drive a motor, a main high-voltage battery and a sub high-voltage battery configured to selectively supply power to the motor system, and a method controlling the vehicle may include monitoring the current state of each of at least two battery cells of the main high-voltage battery when the vehicle is parked, charging the main high-voltage battery for a preset time by allowing a certain amount of a constant current to flow through the sub high-voltage battery, a charging mode deterioration determination step of determining the degree of deterioration for each of the battery cells charged for the preset time, charging the sub high-voltage battery for a preset time by allowing an amount of a constant current to flow through the main high-voltage battery, and determining the degree of deterioration for each of the battery cells discharged for the preset time.

### CROSS-REFERENCE TO RELATED APPLICATIONS

The present application claims priority to Korean Patent Application No. 10-2024-0024307, filed on Feb. 20, 2024, the entire contents of which is incorporated herein for all purposes by this reference.

### BACKGROUND OF THE PRESENT DISCLOSURE

### Field of the Present Disclosure

The present disclosure relates to a method of measuring the degree of aging of a main high-voltage battery of a dual battery system that utilizes a sub high-voltage battery to stably extend the driving range of electric vehicles such as electric vehicles (EV) or plug-in hybrid electric vehicles (PHEV) and a system for the same.

### Description of Related Art

The statements in the present section merely provide background information related to the present disclosure and may not form related art.

As shown in FIG. 1, electrical systems such as electric vehicles (EV) or plug-in hybrid electric vehicles (PHEV), which are in the spotlight as environmental concerns increase worldwide, generally include a motor system 14 including a motor 14a for generating a driving force and an inverter 14b for driving the motor 14a, a main high-voltage battery 11 used as a power source for the motor 14a, a high voltage junction box 12 (hereinafter, referred to as an “HV J/BOX”) for distributing and supplying the high voltage supplied from the main high-voltage battery 11, and a battery management system (BMS) 13 that controls the HV J/BOX 12's distributing voltage and manages the state of the high voltage battery 11.

The component provided drawing reference number 18 is a power controller that is configured to perform overall control of the electrical systems as described above.

Such electrical systems based on a driven motor is a concept commonly used in relation to the current 2nd generation electric vehicles following the 1st generation electric vehicles.

Here, the 2nd generation electric vehicles refer to electric vehicles capable of driving 400 km or more after fully charging the main high-voltage battery 11 once, and have partially met consumers' needs compared to the 1st generation electric vehicles, which are capable of driving approximately 200 km after one full charge. However, the battery performance of the 2nd generation electric vehicles has not improved enough to fully satisfy consumers' needs.

When batteries are used continuously, deterioration or aging, that is, an increase in the internal resistance of the batteries, occurs due to their properties. Even if the same amount of SOC is displayed, as deterioration progresses, a decrease in mileage and output for acceleration, etc. occurs, and if it is not detected properly, unexplained customer complaints may be filed.

Therefore, determining battery deterioration is a very important factor. Typically, to determine battery deterioration based on how much internal resistance has increased, the internal resistance is measured by connecting a battery to a separate internal resistance measuring device or preparing an internal resistance measuring device, or is estimated by modeling and analyzing the voltage output of the current input to the battery.

However, it is not easy to remove the main high-voltage battery 11 mounted on a vehicle to measure internal resistance, and issues regarding time, cost, etc. arise.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to measuring the degree of aging of a main high-voltage battery of a dual battery system using a sub high-voltage battery to stably extend the driving range of electric vehicles such as electric vehicles (EV) or plug-in hybrid electric vehicles (PHEV), and in particular, is aimed at providing a method of measuring the degree of aging of the main high-voltage battery of the dual battery system, where it may be possible to predict the lifespan of a battery by frequently measuring the degree of aging during each of charging and discharging of the main high-voltage battery and managing the history of the measured data or converting it into big data and a system for the same.

According to an exemplary embodiment of the present disclosure, a method of determining a degree of aging of a main high-voltage battery of a vehicle including a motor system configured to drive a motor, a main high-voltage battery configured to selectively supply power to the motor system, and a sub high-voltage battery configured to selectively supply power to the motor system may include monitoring a current state of each of at least two battery cells of the main high-voltage battery while the vehicle is parked, charging the main high-voltage battery for a first preset time by supplying a first current from the sub high-voltage battery, determining a first degree of deterioration for each of the battery cells due to the charging of the main high-voltage battery, discharging the main high-voltage battery for a second preset time by supplying a second current from the main high-voltage battery to the sub high-voltage battery, and determining a second degree of deterioration for each of the battery cells due to the discharging of main high-voltage battery.

Determining the degree of deterioration for each of the battery cells due to the charging of the main high-voltage battery may include determining an internal resistance based on a variance in voltage due to the charging of the main high-voltage battery and the first current.

Determining the degree of deterioration for each of the battery cells due to the discharging of the main high-voltage battery may include determining an internal resistance based on a variance in voltage due to the discharging of the main high-voltage battery and the second current.

The method may further include storing the first degree or the second degree of deterioration in a deterioration learning table for each section of cell voltage.

The method may further include storing the first degree or the second degree of deterioration in a deterioration learning table for each section of a temperature of a battery cell.

The method may further include storing the first degree or the second degree of deterioration in a deterioration learning table for each section of cell voltage and each section of a temperature of a battery cell.

The method may further include updating the deterioration learning table by determining the degree of deterioration of a corresponding section of the deterioration learning table whenever a preset condition is satisfied.

A system for determining a e degree of aging of a main high-voltage battery of a vehicle including a dual battery system according to an exemplary embodiment of the present disclosure may include a motor system configured to drive a motor, a main high-voltage battery configured to selectively supply power to the motor system, a sub high-voltage battery configured to selectively supply power to the motor system, a battery management system (BMS) configured to determine a state of the main high-voltage battery based on a control signal, and a power controller configured to receive the state of the main high-voltage battery, monitor a current status of each of at least two battery cells of the main high-voltage battery while the vehicle is parked, charge the main high-voltage battery for a first preset time by supplying a first current from the sub high-voltage battery, determine a first degree of deterioration for each of the battery cells charged for the preset time due to the charging of the main high-voltage battery, discharge the main high-voltage battery for a second preset time by supplying a second current from the main high-voltage battery to the sub high-voltage battery, and determine a second degree of deterioration for each of the battery cells discharged for the preset time due to the discharging of main high-voltage battery.

The power controller may be further configured to determine an internal resistance based on a variance in voltage due to the charging of the main high-voltage battery and the first current.

The power controller may be further configured to determine an internal resistance based on a variance in voltage due to the discharging of the main high-voltage battery and the second current.

The power controller may be further configured to store the first degree or the second degree of deterioration in a deterioration learning table for each section of cell voltage.

The power controller may be further configured to store the first degree or the second degree of deterioration in a deterioration learning table for each section of a temperature of a battery cell.

The power controller may be further configured to store the first degree or the second degree of deterioration in a deterioration learning table for a section of cell voltage and a section of a temperature of a battery cell.

The power controller may be further configured to update the deterioration learning table by determining the degree of deterioration of a corresponding section of the deterioration learning table whenever a preset condition is satisfied.

Also, according to an exemplary embodiment of the preset disclosure, therein provided a vehicle including a motor configured to drive the vehicle, a motor system configured to drive the motor, a main high-voltage battery configured to selectively supply power to the motor system, a sub high-voltage battery configured to selectively supply power to the motor system, and a power controller configured to receive a state of the main high-voltage battery from a battery management system (BMS), monitor a current status of each of at least two battery cells of the main high-voltage battery while the vehicle is parked, charge the main high-voltage battery for a first preset time by supplying a first current from the sub high-voltage battery, determine a first degree of deterioration for each of the battery cells charged for the preset time due to the charging of the main high-voltage battery, discharge the main high-voltage battery for a second preset time by supplying a second current from the main high-voltage battery to the sub high-voltage battery, determine a second degree of deterioration for each of the battery cells discharged for the preset time due to the discharging of main high-voltage battery, and determine a degree of aging of the main high-voltage battery based on the first and second degrees of deterioration.

In the vehicle, the power controller may be further configured to determine an internal resistance based on a variance in voltage due to the charging of the main high-voltage battery and the first current.

In the vehicle, the power controller may be further configured to determine an internal resistance based on a variance in voltage due to the discharging of the main high-voltage battery and the second current.

In the vehicle, the power controller may be further configured to store the first degree or the second degree of deterioration in a deterioration learning table for each section of cell voltage.

In the vehicle, the power controller may be further configured to store the first degree or the second degree of deterioration in a deterioration learning table for each section of a temperature of a battery cell.

In the vehicle, the power controller may be further configured to store the first degree or the second degree of deterioration in a deterioration learning table for a section of cell voltage and a section of a temperature of a battery cell.

According to an exemplary embodiment of the present disclosure, there may be provided a method of measuring the degree of aging of a main high-voltage battery of a dual battery system and a system for the same, where it may be possible to predict the lifespan of a battery by frequently measuring the degree of aging during each of charging and discharging of the main high-voltage battery of the dual battery system using a sub high-voltage battery to stably extend the driving range of electric vehicles such as electric vehicles (EV) or plug-in hybrid electric vehicles (PHEV) and managing the history of the measured data or converting it into big data.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a block diagram for illustrating an electrical system of a typical electric vehicle.

FIG. 2 is a block diagram for illustrating components of a dual battery system including a sub high-voltage battery according to an exemplary embodiment of the present disclosure.

FIG. 3 is a block diagram for illustrating components of a dual battery system including a sub high-voltage battery according to another exemplary embodiment of the present disclosure.

FIG. 4A and FIG. 4B are a flowchart for illustrating a method of measuring the degree of aging of a main high-voltage battery of a dual battery system according to an exemplary embodiment of the present disclosure.

FIG. 5 is a view for illustrating the concept of determining internal resistance of the method of measuring the degree of aging of the main high-voltage battery of the dual battery system according to an exemplary embodiment of the present disclosure.

FIG. 6 is a view for illustrating a deterioration measurement learning table generated by the method of measuring the degree of aging of the main high-voltage battery of the dual battery system according to an exemplary embodiment of the present disclosure.

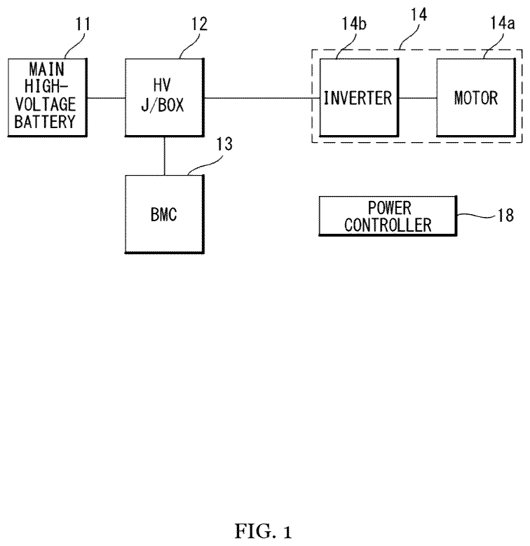

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Because various changes may be made to the present disclosure and a range of embodiments may be made for the present disclosure, specific embodiments will be illustrated and described in the drawings. However, this is not intended to limit the present disclosure to the specific embodiments, and it should be understood that the present disclosure includes all changes, equivalents, and substitutes within the technology and the scope of the present disclosure.

The terms “module” and “unit” used in an exemplary embodiment of the present disclosure are merely used to distinguish the names of components, and should not be interpreted as assuming that the components have been physically or chemically separated or may be so separated.

Terms including ordinal numbers such as “first” and “second” may be used to describe various components, but the components are not limited by the terms. The above-mentioned terms may be used only as names to distinguish one component from another component, and the order therebetween may be determined by the context in the descriptions thereof, not by such names.

The expression “and/or” is used to include all possible combinations of multiple items being addressed. For example, by “A and/or B,” all three possible combinations are meant: “A,” “B,” and “A and B.”

When a component is said to be “coupled” or “connected” to another component, it means that the component may be directly coupled or connected to the other component or there may be other components therebetween.

The terms used herein are only used to describe specific embodiments and are not intended to limit the present disclosure. Expressions in the singular form include the meaning of the plural form unless they clearly mean otherwise in the context. In an exemplary embodiment of the present disclosure, expressions such as “comprise” or “have” are intended to indicate the presence of features, numbers, steps, operations, components, parts, or combinations thereof described herein, and should not be understood as precluding the possibility of the presence or the addition of one or more other features, numbers, steps, operations, components, parts, or combinations thereof.

Unless otherwise defined, all terms used herein, including technical or scientific terms, have meanings commonly understood by a person having ordinary skill in the field of the present disclosure to which the present disclosure pertains. Terms defined in commonly used dictionaries should be interpreted as including meanings consistent with the meanings they have in the context of the relevant technology, and should not be interpreted in an ideal or overly formal sense unless explicitly defined in an exemplary embodiment of the present disclosure.

Furthermore, a unit, a control unit, a control device, or a controller is only a term widely used to name devices for controlling a certain function, and do not mean a generic function unit. For example, devices with these names may include a communication device that communicates with other controllers or sensors to control a certain function, a computer-readable recording medium that stores an operating system, logic instructions, input/output information, etc., and one or more processors that perform operations of determination, calculation, making decisions, etc. required to control the function.

Meanwhile, the processor may include a semiconductor integrated circuit and/or electronic devices that carry out operations of at least one of comparison, determination, calculation, and making decisions to perform a programmed function. For example, the processor may be any one or a combination of a computer, a microprocessor, a CPU, an ASIC, and an electronic circuit such as circuitry and logic circuits.

Examples of a computer-readable recording medium (or simply called a memory) may include all types of storage devices for storing data that can be read by a computer system. For example, they may include at least one of a memory such as a flash memory, a hard disk, a micro memory, and a card memory, e.g., a secure digital card (SD card) or an eXtream digital card (XD card), and a memory such as a random access memory (RAM), a static ram (SRAM), a read-only memory (ROM), a programmable ROM (PROM), an electrically erasable PROM (EEPROM), a magnetic RAM (MRAM), a magnetic disk, and an optical disk.

Such a recording medium may be electrically connected to the processor, and the processor may load and write data from the recording medium. The recording medium and the processor may be integrated or physically separate.

Hereinafter, a method of measuring the degree of aging of a main high-voltage battery of a dual battery system according to an exemplary embodiment of the present disclosure and a system for the same will be described with reference to the appended drawings.

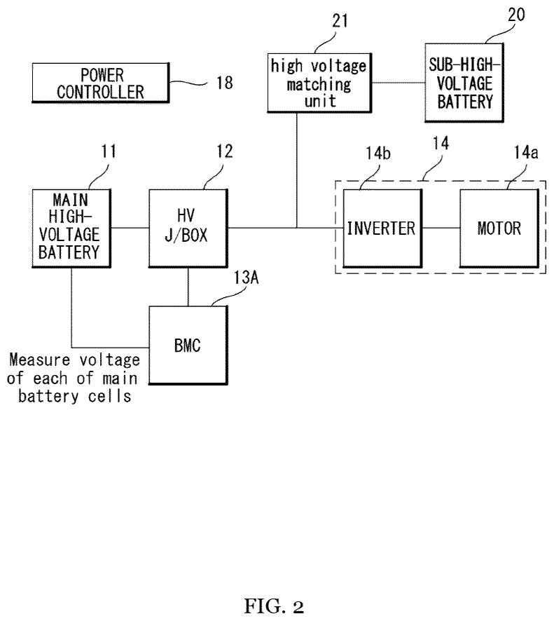

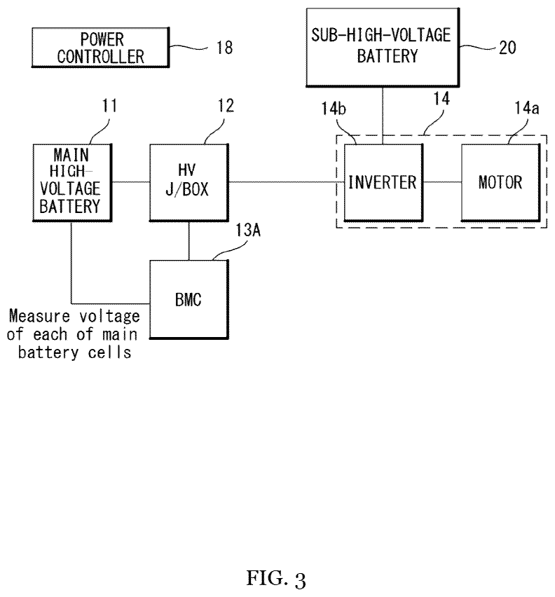

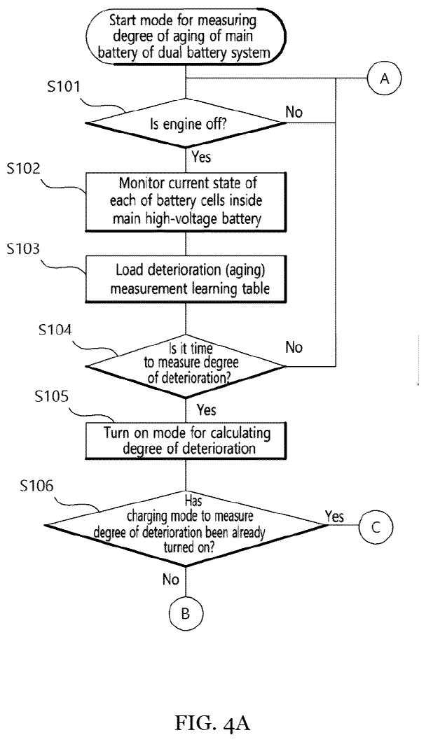

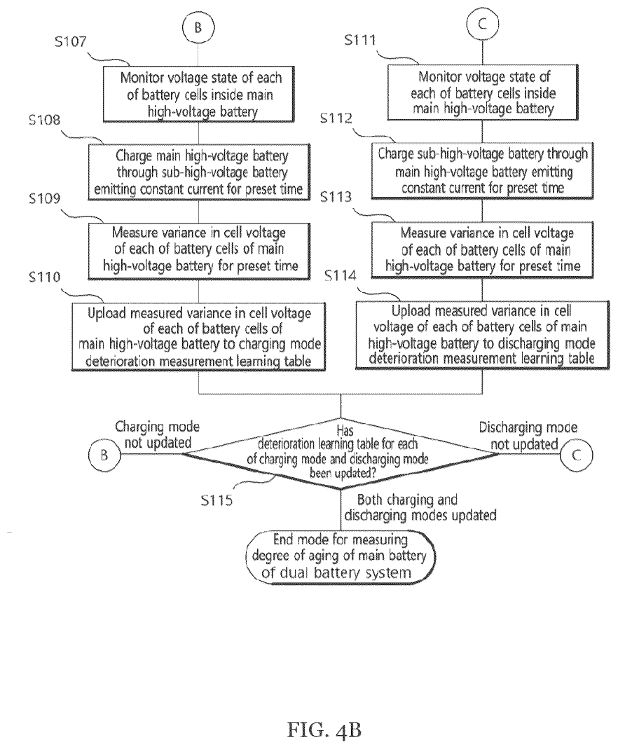

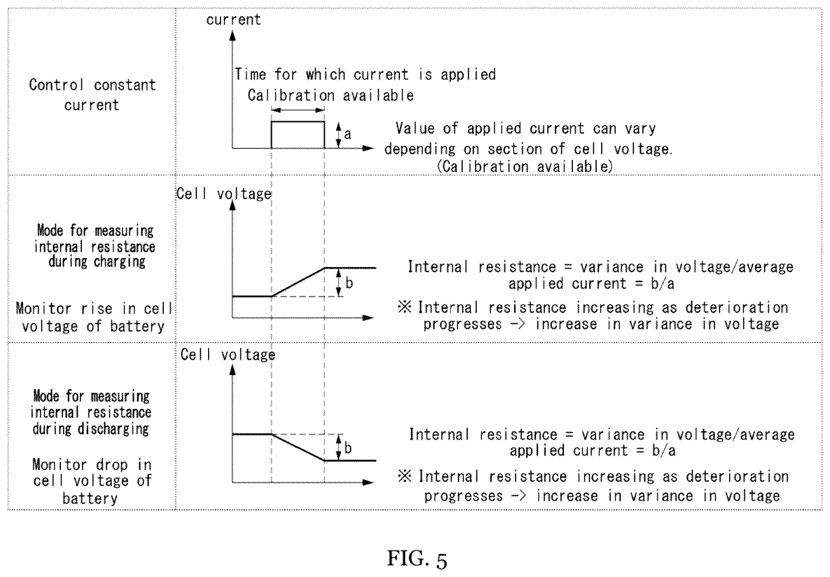

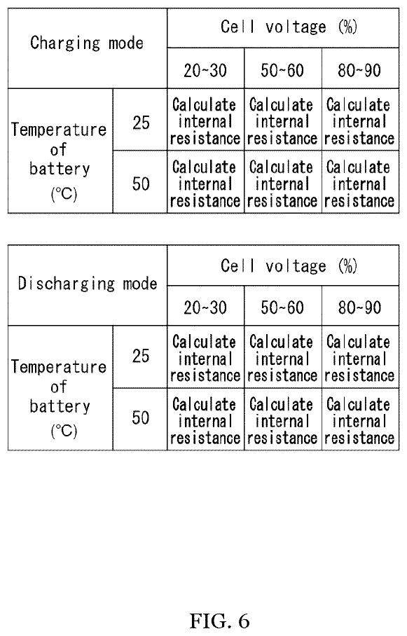

FIG. 2 is a block diagram for showing components of a dual battery system including a sub high-voltage battery according to an exemplary embodiment of the present disclosure, FIG. 3 is a block diagram for showing components of a dual battery system including a sub high-voltage battery according to another exemplary embodiment of the present disclosure, FIG. 4A and FIG. 4B are a flowchart for illustrating the method of measuring the degree of aging of the main high-voltage battery of the dual battery system according to an exemplary embodiment of the present disclosure, FIG. 5 is a view for illustrating the concept of determining internal resistance of the method of measuring the degree of aging of the main high-voltage battery of the dual battery system according to an exemplary embodiment of the present disclosure, and FIG. 6 is a view for illustrating a deterioration measurement learning table generated by the method of measuring the degree of aging of the main high-voltage battery of the dual battery system according to an exemplary embodiment of the present disclosure.

The dual battery system in FIG. 2 and FIG. 3 to which the present disclosure is applied may further include a sub high-voltage battery 20 in a conventional power system as shown in the drawings.

Here, it is assumed that the main high-voltage battery 11 and the sub high-voltage battery 20 are different in capacity and capability.

Therefore, for example, assuming that the main high-voltage battery 11 may include a capability of 123 Kwh (697 volts), the sub high-voltage battery 20 may be assumed to include a capability of 30 Kwh (174 volts), which is approximately 20 to 25 percent of the capability of the main high-voltage battery 11.

However, it should be noted that the present disclosure is not limited thereto.

In the case of the structure in FIG. 2, a converter such as a high voltage matching unit 21 (e.g., a high voltage DC-DC converter (HDC)) is required to adjust the voltage of each of the main high-voltage battery 11 and the sub high-voltage battery 20 to the voltage assumed above, and in the case of the structure in FIG. 3, with the motor system 14, no additional device is needed.

The technology shown in FIG. 2 and FIG. 3 is called a dual battery system, and the dual battery system may charge the main high-voltage battery 11 through the sub high-voltage battery 20 or is configured as an auxiliary power source for driving the motor 14a. Furthermore, the main high-voltage battery 11 may also supplement and charge the sub high-voltage battery 20 as needed.

Here, in a process of measuring the degree of deterioration or aging of the main high-voltage battery 11 of the dual battery system as described above, both a charging mode and a discharging mode of the main high-voltage battery 11 may be performed, and measurement data in each mode may be stored in a learning table, as in the exemplary embodiment in FIG. 4A and FIG. 4B.

Such an operation may be managed by a power controller 18 of the dual battery system shown in FIG. 2 and FIG. 3.

As for the process shown in FIG. 4A and FIG. 4B, at S101, the power controller 18 may be configured to determine whether a vehicle's engine is currently off.

When it is determined at S101 that the vehicle's engine is off, the process may move on to S102 and the current state of each of at least two battery cells of the main high-voltage battery 11 may be monitored through a BMS 13A.

Thereafter, at S103, a deterioration (aging) measurement learning table may be loaded from a memory, an example of which is shown in FIG. 6.

It should be noted that features of the deterioration measurement learning table are not limited to the example in FIG. 6.

Based on a deterioration measurement learning table updated at a previous time through the processes in S102 and S103 described above and the current monitoring value, or whether a preset time has elapsed since the last update, at S104, it may be determined whether it is time to measure the degree of deterioration.

When it is determined at S104 that it is time to measure the degree of deterioration, the power controller 18 may move on to S105 and turn on a mode for determining the degree of deterioration.

Accordingly, at S106, it may be determined whether a charging mode to measure the degree of deterioration has been already turned on. When the charging mode to measure the degree of deterioration is not determined to have been turned on, the process may move on to S107, and when it is determined to have been turned on, the process may move on to S111.

At S107, the voltage status of each of at least two battery cells inside the main high-voltage battery 11 may be monitored, and proceeding to S108, a certain amount of a constant current may flow through the sub high-voltage battery 20 for a preset time to charge the main high-voltage battery 11.

The preset time may be set to between 5 and 30 seconds, but is not limited thereto. Furthermore, the magnitude of the constant current may also be adjusted as needed, but is not limited to a specific value in the description of the present disclosure.

While the sub high-voltage battery 20 is charging the main high-voltage battery 11 at S108, the variance in cell voltage of each of at least two battery cells of the main high-voltage battery 11 may be measured at S109.

In FIG. 5, the processes in S107 to S109 are graphically expressed.

Thereafter, at S110, the measured variance in cell voltage of each of at least two battery cells of the main high-voltage battery 11 may be uploaded to a charging mode deterioration measurement learning table.

Here, as shown in FIG. 6, the charging mode deterioration measurement learning table may include tables based on predetermined ranges of the cell voltage and predetermined temperatures of a battery cell, not limited thereto. The upper table in FIG. 6 shows 20˜30% as a first range of cell voltage, 50˜60% as a second range of cell voltage, and 80˜90% as a third range of cell voltage, and also the table shows 25° C. and 50° C. as predetermined temperatures.

The processes in the above-described S107 to S110 may be performed while the main high-voltage battery 11 is being charged.

In contrast, at S111, the voltage status of each of at least two battery cells inside the main high-voltage battery 11 may be monitored, and proceeding to S112, a certain amount of a constant current may flow through the main high-voltage battery 11 for a preset time to charge the sub high-voltage battery 20.

The preset time may be set to between 5 and 30 seconds, but is not limited thereto. Furthermore, the magnitude of the constant current may also be adjusted as needed, but is not limited to a specific value in the description of the present disclosure.

While the main high-voltage battery 11 is charging the sub high-voltage battery 20 at S112, the variance in cell voltage of each of at least two battery cells of the main high-voltage battery 11 may be measured at S113.

In FIG. 5, the processes in S111 to S113 are graphically expressed.

Thereafter, at S114, the measured variance in cell voltage of each of at least two battery cells of the main high-voltage battery 11 may be uploaded to a discharging mode deterioration measurement learning table.

Here, as shown in FIG. 6, the discharging mode deterioration measurement learning table may include tables classified according to cell voltage and temperature of a battery cell, not limited thereto. The lower table in FIG. 6 shows 20˜30% as a first range of cell voltage, 50˜60% as a second range of cell voltage, and 80˜90% as a third range of cell voltage, and also the table shows 25° C. and 50° C. as predetermined temperatures.

The processes in the above-described S111 to S114 may be performed while the main high-voltage battery 11 is being discharged.

Accordingly, at S115, it may be determined whether a deterioration learning table for each of the charging mode and the discharging mode has been updated, and when there is a non-updated mode, the mode may be performed.

When it is determined at S115 that the deterioration learning table for each of the charging mode and the discharging mode has been updated, the measurement of the degree of aging may end.

In addition, the term related to a control device such as “controller”, “control apparatus”, “control unit”, “control device”, “control module”, “control circuit”, or “server”, etc refers to a hardware device including a memory and a processor configured to execute one or more steps interpreted as an algorithm structure. The memory stores algorithm steps, and the processor executes the algorithm steps to perform one or more processes of a method in accordance with various exemplary embodiments of the present disclosure. The control device according to exemplary embodiments of the present disclosure may be implemented through a nonvolatile memory configured to store algorithms for controlling operation of various components of a vehicle or data about software commands for executing the algorithms, and a processor configured to perform operation to be described above using the data stored in the memory. The memory and the processor may be individual chips. Alternatively, the memory and the processor may be integrated in a single chip. The processor may be implemented as one or more processors. The processor may include various logic circuits and operation circuits, may process data according to a program provided from the memory, and may generate a control signal according to the processing result.

The control device may be at least one microprocessor operated by a predetermined program which may include a series of commands for carrying out the method disclosed in the aforementioned various exemplary embodiments of the present disclosure.

In various exemplary embodiments of the present disclosure, the memory and the processor may be provided as one chip, or provided as separate chips.

In various exemplary embodiments of the present disclosure, the scope of the present disclosure includes software or machine-executable commands (e.g., an operating system, an application, firmware, a program, etc.) for enabling operations according to the methods of various embodiments to be executed on an apparatus or a computer, a non-transitory computer-readable medium including such software or commands stored thereon and executable on the apparatus or the computer.

In various exemplary embodiments of the present disclosure, the control device may be implemented in a form of hardware or software, or may be implemented in a combination of hardware and software.

Software implementations may include software components (or elements), object-oriented software components, class components, task components, processes, functions, attributes, procedures, subroutines, program code segments, drivers, firmware, microcode, data, database, data structures, tables, arrays, and variables. The software, data, and the like may be stored in memory and executed by a processor. The memory or processor may employ a variety of means well known to a person having ordinary knowledge in the art.

Furthermore, the terms such as “unit”, “module”, etc. included in the specification mean units for processing at least one function or operation, which may be implemented by hardware, software, or a combination thereof.

In the flowchart described with reference to the drawings, the flowchart may be performed by the controller or the processor. The order of operations in the flowchart may be changed, a plurality of operations may be merged, or any operation may be divided, and a predetermined operation may not be performed. Furthermore, the operations in the flowchart may be performed sequentially, but not necessarily performed sequentially. For example, the order of the operations may be changed, and at least two operations may be performed in parallel.

Hereinafter, the fact that pieces of hardware are coupled operatively may include the fact that a direct and/or indirect connection between the pieces of hardware is established by wired and/or wirelessly.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the present specification, unless stated otherwise, a singular expression includes a plural expression unless the context clearly indicates otherwise.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A method of determining a degree of aging of a main high-voltage battery of a vehicle including a motor system configured to drive a motor, a main high-voltage battery configured to selectively supply power to the motor system, and a sub high-voltage battery configured to selectively supply power to the motor system, the method comprising:
monitoring, by a controller, a current state of each of at least two battery cells of the main high-voltage battery while the vehicle is parked;
charging, by the controller, the main high-voltage battery for a first preset time by supplying a first current from the sub high-voltage battery operatively connected to the main high-voltage battery;
determining, by the controller, a first degree of deterioration for each of the at least two battery cells due to the charging of the main high-voltage battery;
discharging, by the controller, the main high-voltage battery for a second preset time by supplying a second current from the main high-voltage battery to the sub high-voltage battery; and
determining, by the controller, a second degree of deterioration for each of the at least two battery cells due to the discharging of main high-voltage battery.

2. The method of claim 1, wherein the determining of the first degree of deterioration for each of the at least two battery cells due to the charging of the main high-voltage battery includes determining an internal resistance based on a variance in voltage due to the charging of the main high-voltage battery and the first current.

3. The method of claim 1, wherein the determining of the second degree of deterioration for each of the at least two battery cells due to the discharging of the main high-voltage battery includes determining an internal resistance based on a variance in voltage due to the discharging of the main high-voltage battery and the second current.

4. The method of claim 1, further including storing the first degree or the second degree of deterioration in a deterioration learning table for each predetermined range of cell voltage.

5. The method of claim 1, further including storing the first degree or the second degree of deterioration in a deterioration learning table for each predetermined range of a temperature of a battery cell.

6. The method of claim 1, further including storing the first degree or the second degree of deterioration in a deterioration learning table for each section of cell voltage and each section of a temperature of a battery cell.

7. The method of claim 4, further including updating the deterioration learning table whenever a preset condition is satisfied.

8. A system for determining a degree of aging of a main high-voltage battery of a vehicle, the system comprising:
a motor system including a motor and configured to drive the motor;
the main high-voltage battery configured to selectively supply power to the motor system;
a sub high-voltage battery configured to selectively supply power to the motor system;
a battery management system (BMS) configured to determine a state of the main high-voltage battery based on a control signal; and
a controller configured to:
receive the state of the main high-voltage battery,
monitor a current status of each of at least two battery cells of the main high-voltage battery while the vehicle is parked,
charge the main high-voltage battery for a first preset time by supplying a first current from the sub high-voltage battery,
determine a first degree of deterioration for each of the at least two battery cells charged for the first preset time due to the charging of the main high-voltage battery,
discharge the main high-voltage battery for a second preset time by supplying a second current from the main high-voltage battery to the sub high-voltage battery, and
determine a second degree of deterioration for each of the at least two battery cells discharged for the second preset time due to the discharging of main high-voltage battery.

9. The system of claim 8, wherein the controller is further configured to determine an internal resistance based on a variance in voltage due to the charging of the main high-voltage battery and the first current.

10. The system of claim 8, wherein the controller is further configured to determine an internal resistance based on a variance in voltage due to the discharging of the main high-voltage battery and the second current.

11. The system of claim 8, wherein the controller is further configured to store the first degree or the second degree of deterioration in a deterioration learning table for each section of cell voltage.

12. The system of claim 8, wherein the controller is further configured to store the first degree or the second degree of deterioration in a deterioration learning table for each section of a temperature of a battery cell.

13. The system of claim 8, wherein the controller is further configured to store the first degree or the second degree of deterioration in a deterioration learning table for a section of cell voltage and a section of a temperature of a battery cell.

14. The system of claim 11, wherein the controller is further configured to update the deterioration learning table by determining a degree of deterioration of a corresponding section of the deterioration learning table whenever a preset condition is satisfied.

15. A vehicle comprising:
a motor configured to drive the vehicle;
a motor system including the motor and configured to drive the motor;
a main high-voltage battery configured to selectively supply power to the motor system;
a sub high-voltage battery configured to selectively supply power to the motor system; and
a controller configured to
receive a state of the main high-voltage battery from a battery management system (BMS);
monitor a current status of each of at least two battery cells of the main high-voltage battery while the vehicle is parked;
charge the main high-voltage battery for a first preset time by supplying a first current from the sub high-voltage battery operatively connected to the main high-voltage battery;
determine a first degree of deterioration for each of the at least two battery cells charged for the first preset time due to the charging of the main high-voltage battery;
discharge the main high-voltage battery for a second preset time by supplying a second current from the main high-voltage battery to the sub high-voltage battery;
determine a second degree of deterioration for each of the at least two battery cells discharged for the second preset time due to the discharging of main high-voltage battery; and
determine a degree of aging of the main high-voltage battery based on the first and second degrees of deterioration.

16. The vehicle of claim 15, wherein the controller is further configured to determine an internal resistance based on a variance in voltage due to the charging of the main high-voltage battery and the first current.

17. The vehicle of claim 15, wherein the controller is further configured to determine an internal resistance based on a variance in voltage due to the discharging of the main high-voltage battery and the second current.

18. The vehicle of claim 15, wherein the controller is further configured to store the first degree or the second degree of deterioration in a deterioration learning table for each section of cell voltage.

19. The vehicle of claim 15, wherein the controller is further configured to store the first degree or the second degree of deterioration in a deterioration learning table for each section of a temperature of a battery cell.

20. The vehicle of claim 15, wherein the controller is further configured to store the first degree or the second degree of deterioration in a deterioration learning table for a section of cell voltage and a section of a temperature of a battery cell.
